(19) United States
(12) Patent Application Publication
(10) Pub. No.: US 2023/0229832 A1
(43) Pub. Date: Jul. 20, 2023

(54) METHODS AND SYSTEMS FOR VEHICLE ANALYTICS WITH SIMULATED DATA

(71) Applicant: Dana Heavy Vehicle Systems Group, LLC, Maumee, OH (US)

(72) Inventor: Theyaa Matti, Maumee, OH (US)

(21) Appl. No.: 17/648,162

(22) Filed: Jan. 17, 2022

(51) Int. Cl. G06F 30/27

(52) U.S. Cl. CPC G06F 30/27

(57) ABSTRACT

Methods and systems are disclosed for generating simulated vehicle performance data. In one example, a method includes building a vehicle model based on sensor data collected from one or more training vehicles, generating a simulation set of virtual vehicles based on the vehicle model, executing a simulation of each of the simulation set of vehicles a plurality of instances, each instance executed with different simulation vehicle operating parameters, obtaining simulation vehicle data from each of the simulation set of vehicles at each instance, training a machine learning model with the simulation vehicle data, and setting one or more parameters of one or more real vehicles based on output from the trained machine learning model.

### TECHNICAL FIELD

The present disclosure relates generally to generating simulated vehicle performance data for more robust data analytics.

### BACKGROUND AND SUMMARY

A performance of vehicles may be improved by analyzing data generated during operation of the vehicles. The data may be collected from the vehicles during operation under different conditions, such as on different routes, with different road conditions, with different drivers, and/or under different environmental conditions. Once sufficient data has been collected, various analytics techniques and approaches may be applied to the data to determine how vehicle performance may be improved. As an example, machine learning (ML) may be used to identify optimal settings of operational parameters of one or more subsystems of the vehicles that increase an efficiency of the one or more subsystems. For example, parameters of vehicle subsystems involved in energy regeneration may be optimized to increase an amount of energy regenerated during vehicle operation.

However, the inventors herein have recognized that generating sufficient data to build robust analytics solutions may be problematic or unfeasible. For certain vehicles, such as new vehicle models or vehicles typically deployed in commercial fleets with typical commercial fleet sizes, it may take a long time to collect enough data to adequately train an ML model, and a distribution of the data collected with respect to a range of vehicle and driving conditions may be skewed. As a result, a time frame for developing performance enhancements for a specific model or type of vehicle may be too short to effectively apply high-dimensional analytics solutions to data collected during commercial vehicle operation. This may apply to specialized vehicles such as battery-electric vehicles (BEVs), as there may be less models in operation.

In various embodiments, the issues described above may be addressed by a method, comprising building a vehicle model based on sensor data collected from one or more training vehicles; generating a simulation set of virtual vehicles based on the vehicle model; executing a simulation of each of the simulation set of vehicles a plurality of instances, each instance executed with different simulation vehicle operating parameters; obtaining simulation vehicle data from each of the simulation set of vehicles at each instance; training a machine learning model with the simulation vehicle data; and setting one or more parameters of one or more real vehicles based on output from the trained machine learning model. By using performance data generated by virtual vehicles rather than real vehicles, an amount of data available for training an ML model may be increased, as a result of not being dependent on a number of real vehicles or driving conditions encountered in the real world. Since virtual vehicle operation may be simulated in a distributed compute environment, such as in a cloud with on-demand resource allocation, virtual vehicle simulation may be performed in parallel, reducing an amount of time spent collecting data. Additionally, the routes and conditions under which the performance data is collected from the virtual vehicles may be controlled to ensure a healthy distribution of data, which may decrease training time and increase an accuracy of a trained model. By decreasing the time spent collecting data and the time spent training the ML model, a development and deployment time for performance enhancements based on ML model performance may be reduced. An additional advantage of the methods and systems described herein is that a cost of developing and deploying performance enhancements may be more accurately predicted and controlled, leading to greater vehicle efficiency at lower cost.

The above advantages and other advantages, and features of the present description will be readily apparent from the following Detailed Description when taken alone or in connection with the accompanying drawings. It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The disclosure may be better understood from reading the following description of non-limiting embodiments, with reference to the attached drawings, wherein below:

FIG. 1 is a schematic representation of a cloud-based system for simulating operation of a plurality of virtual vehicles, in accordance with one or more embodiments of the present disclosure;

FIG. 2A is a schematic representation of a first portion of a model of a vehicle, in accordance with one or more embodiments of the present disclosure;

FIG. 2B is a schematic representation of a second portion of a model of a vehicle, in accordance with one or more embodiments of the present disclosure;

FIG. 2C is a schematic representation of components of a cloud ecosystem interacting with a model of a vehicle, in accordance with one or more embodiments of the present disclosure;

FIG. 3 is a high-level flowchart that illustrates an exemplary method for training a machine learning model on vehicle simulation data, in accordance with one or more embodiments of the present disclosure; and

FIG. 4 is a flowchart that illustrates an exemplary method for generating training data of a machine learning model from vehicle simulation data, in accordance with one or more embodiments of the present disclosure.

### DETAILED DESCRIPTION

The methods and systems described herein refer to a framework for increasing an amount of training data available for training a high-dimensional statistical model, such as a machine learning (ML) model, to increase a performance of a vehicle. In an embodiment, a cloud-based system includes a simulation engine that may generate a plurality of virtual vehicles based on a physics-based vehicle model of a real vehicle. An operation of each virtual vehicle of the plurality of virtual vehicles may be simulated by the simulation engine, under various conditions and scenarios, with performance data being collected. Additionally, the operation of each virtual vehicle may be simulated in parallel, by leveraging on-demand processing and memory resources of the cloud-based system. As a result of the parallelization of the simulations, a larger amount of operational performance data of the virtual vehicles may be collected than an amount that may be feasibly collected from a plurality of real vehicles. The ML model may subsequently be trained to determine a set of parameters of the vehicle model that optimizes a performance of one or more systems of the vehicle model, such as an energy regeneration system. An optimized set of parameters generated by a trained ML model may then be transmitted to the plurality of real vehicles, resulting in an increased performance of the plurality of real vehicles.

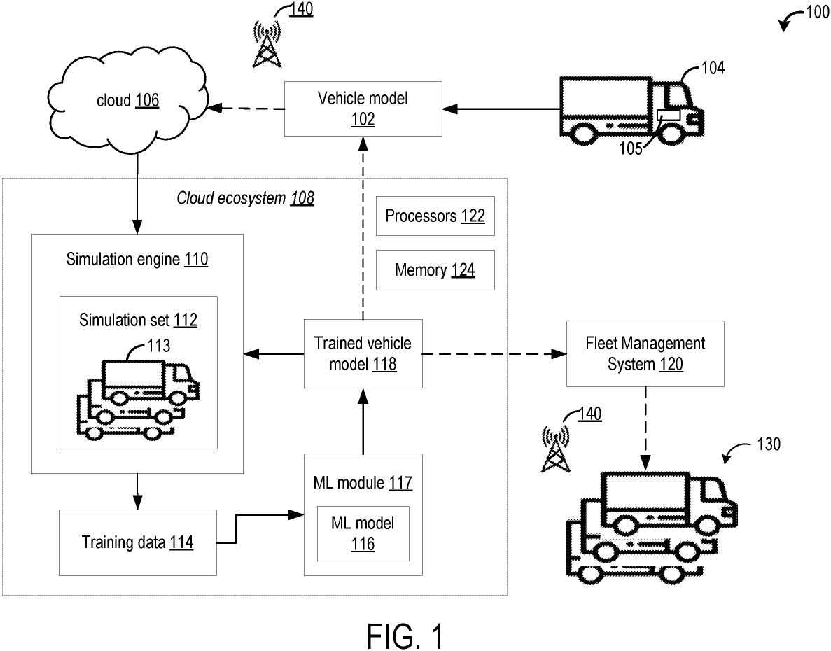

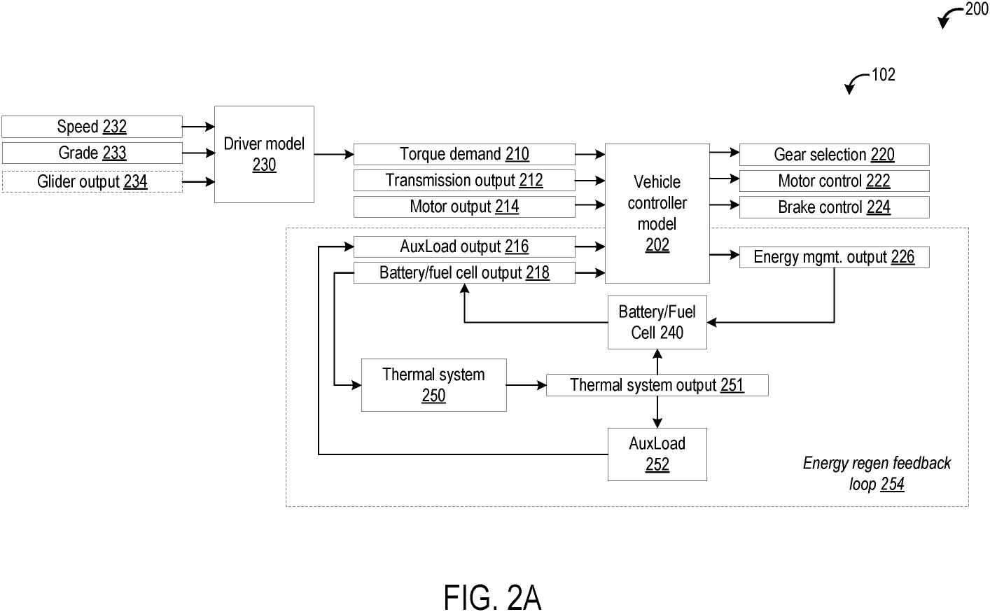

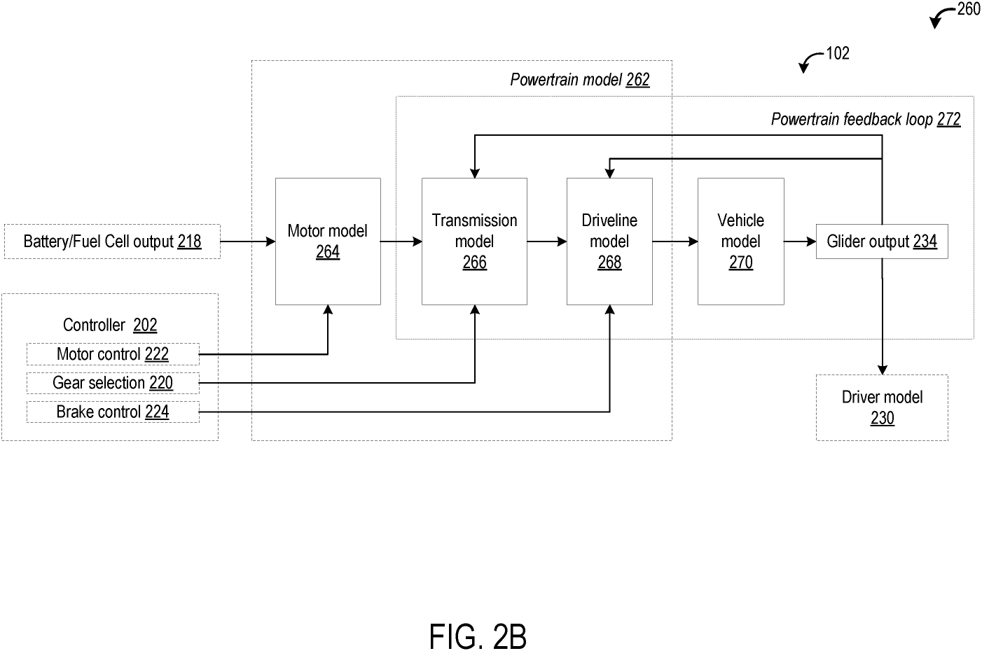

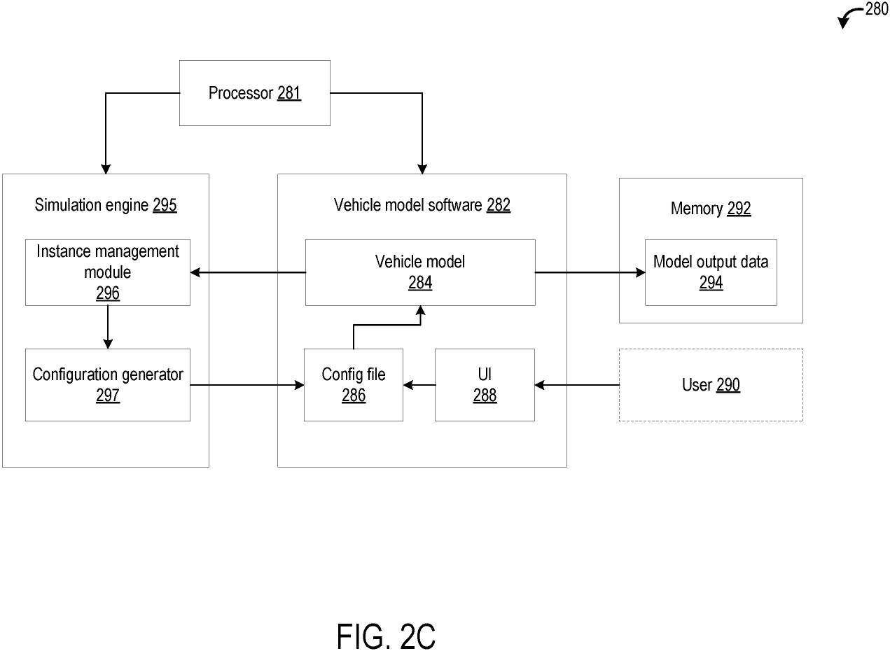

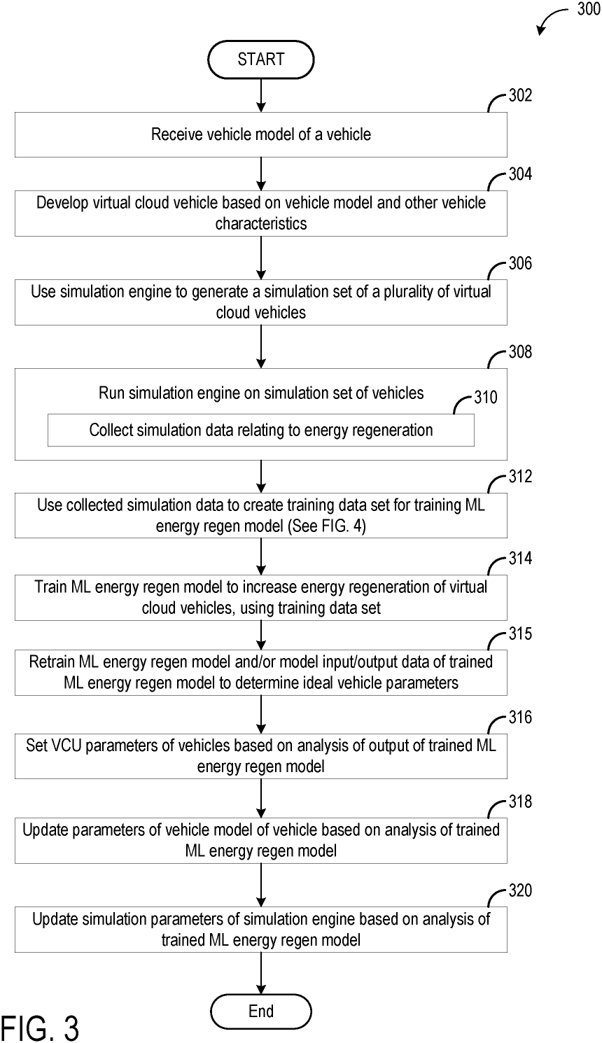

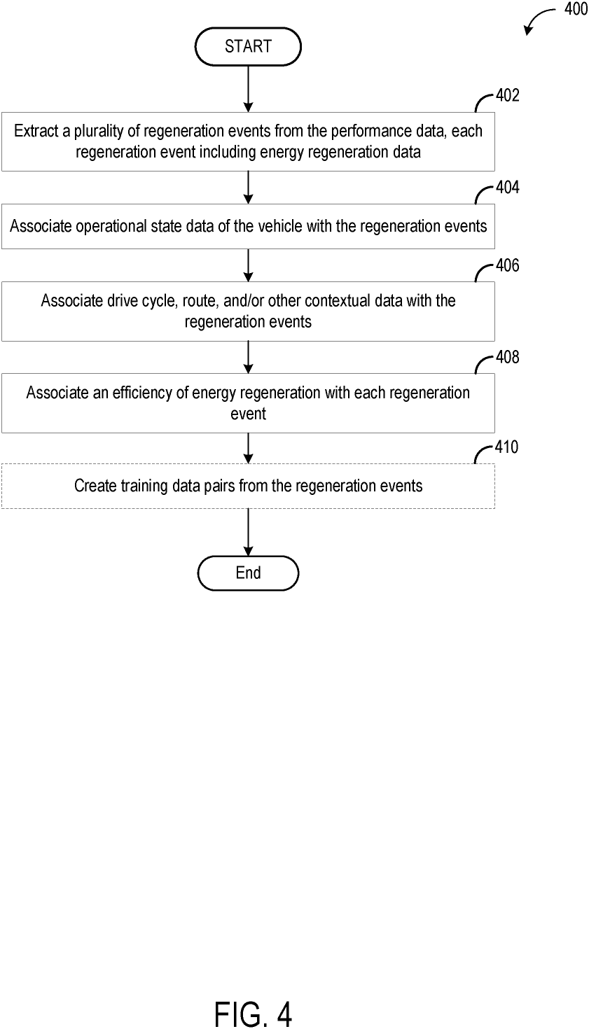

A cloud-based system for simulating operation of a plurality of virtual vehicles is shown in FIG. 1. Each virtual vehicle of the plurality of virtual vehicles may be based on a vehicle model of a real vehicle. A first portion of the vehicle model including a driver model and a vehicle controller model is shown in FIG. 2A, and a second portion of the vehicle model including a powertrain model and a vehicle model is shown in FIG. 2B. The vehicle model may be bundled in software that supports flexible configuration for parallelized simulation, as shown in FIG. 2C. FIG. 3 describes a method for generating simulated vehicle data and training an ML model of the cloud-based system. A training data set for training the ML model may be generated from the simulation data by following one or more steps of the method described in FIG. 4.

Referring now to FIG. 1, a vehicle performance enhancement system 100 is shown for simulating operation of a plurality of virtual vehicles, based on the operation of a real vehicle, and subsequently training an ML model on data collected from the plurality of virtual vehicles to improve a performance of the real vehicle. Specifically, the ML model may be trained to output a set of parameters of one or more vehicle systems of the real vehicle, which may maximize a performance and/or an efficiency of the one or more vehicle systems.

Vehicle performance enhancement system 100 may include a vehicle model 102 of a vehicle 104. In various embodiments, vehicle 104 may be truck of a fleet 130 of trucks. For example, fleet 130 may be a fleet of delivery trucks for a commercial distributor. Vehicle 104 is a real-world, physical vehicle and thus may include vehicle systems and components 105, which may include but is not limited to a motor, a battery/fuel cell, a transmission, a suspension system, a brake system, a vehicle heating, ventilation, and cooling (HVAC) system, cabin accessories (e.g., in-vehicle entertainment system), and a vehicle control unit (VCU). The VCU may store in memory various calibratable vehicle parameters, which may include motor parameters (e.g., motor torque as a function of accelerator pedal position), transmission parameters, battery parameters, auxiliary load parameters, etc. In a specific example, the calibratable vehicle parameters may include parameters relating to regenerative braking, such as conditions that trigger regenerative braking, how much braking torque is applied via regenerative braking and how much braking torque is applied via friction braking during a given braking event (referred to as a brake torque split), and/or a regenerative braking torque threshold.

Vehicle model 102 may model various elements and/or subsystems of vehicle 104, such as a controller, a powertrain, physical characteristics of vehicle 104, and the like. Thus, vehicle 104 may be referred to as a training vehicle. In various embodiments, the vehicle model may be a computer model of a software program comprising various subsystem models, each subsystem model receiving one or more inputs and generating one or more outputs that may be inputted back into one or more of the subsystem models. In other words, vehicle model 102 may comprise various feedback loops between internal components, whereby an initial set of parameters (e.g., driver data, route data, weather data, vehicle data) may be inputted into vehicle model 102 and simulated operational (e.g., vehicle performance) data of vehicle 104 may be generated and collected based on the initial set of parameters over a drive cycle. In various embodiments, vehicle model 102 may be created based on historical and/or statistical information collected from a plurality of vehicles 104 of fleet 130, for example, at a lab of a manufacturer of vehicle 104. Vehicle model 102 may be built based on sensor and controller data collected from vehicle 104, including vehicle sensor data obtained from sensors installed on vehicle 104 (and that may be installed on one or more vehicles of fleet 130) and instrumentation sensor data obtained from non-vehicle sensors (e.g., from a dynamometer on which vehicle 104 is operated) and/or sensors that are specifically installed on vehicle 104 for the purposes of model generation (and hence are not installed on any vehicles of fleet 130). Vehicle model 102 is described in greater detail below in reference to FIGS. 2A, 2B, and 2C.

Vehicle performance enhancement system 100 may include a cloud 106, and vehicle model 102 may be uploaded to a cloud ecosystem 108 of cloud 106 over a network 140, which may be a suitable wired or wireless network (e.g., the Internet). In various embodiments, network 140 may include a wireless cellular network to which vehicle 104 is connected. Cloud ecosystem 108 may include a simulation engine 110, training data 114, and an ML module 117 that generates a trained vehicle model 118.

Simulation engine 110 may generate a simulation set 112 of a plurality of virtual vehicles 113, where each virtual vehicle 113 is based on vehicle model 102. Simulation set 112 may include tens of thousands of vehicles, or hundreds of thousands of vehicles, or millions of vehicles. In some embodiments, each virtual vehicle 113 of simulation set 112 may include the same or substantially similar parameters, while in other embodiments, each virtual vehicle 113 may include different parameters. For example, each virtual vehicle 113 may be assigned an initial set of parameters of vehicle model 102 that have been adjusted to reflect variability and/or differences (e.g., age, wear, size, weight) between each vehicle 104 of fleet 130. For example, a first virtual vehicle 113 may be initialized with a set of parameters of vehicle model 102 corresponding to a new truck of a first size; a second virtual vehicle 113 may be initialized with a set of parameters of vehicle model 102 corresponding to a new truck of a second size; a third virtual vehicle 113 may be initialized with a set of parameters of vehicle model 102 corresponding to an older truck of the first size; a fourth virtual vehicle 113 may be initialized with a set of parameters of vehicle model 102 corresponding to an older truck of the second size; and so on. In some examples, when different virtual vehicles are initialized with different sets of parameters, multiple copies/versions of each different virtual vehicle may be generated. For example, multiple copies of the first virtual vehicle may be generated, multiple copies of the second virtual vehicle may be generated, etc.

Each virtual vehicle 113 may also be assigned an initial set of drive cycle parameters defining an assigned route or drive cycle, driver style, and driving conditions. The driving conditions may include, for example, road conditions, weather conditions, lighting conditions (e.g., a time of day/night), environmental conditions (e.g., heat, cold), and the like. The initial drive cycle parameters may similarly be adjusted to cover a range of different routes and conditions, to ensure that data collected has a desired distribution.

Simulation engine 110 may initiate a virtual vehicle simulation, where an operation of each virtual vehicle 113 of simulation set 112 is simulated individually. In various embodiments, two or more or each of the individual simulations may be performed concurrently. Specifically, simulation engine 110 may be built using software technologies (including open-source software technologies) designed to run in a distributed compute environment, such that simulation of the operation of each virtual vehicle 113 may be carried out in parallel, to facilitate horizontal scaling to a desired size. During the virtual vehicle simulation, performance and other data of each virtual vehicle 113 may be collected. The operation of each virtual vehicle 113 may be simulated under different conditions, as described above. For example, the virtual vehicles 113 may operate on different virtual routes, at different times of the day, during different seasons and during different environmental and/or climactic conditions, and so on. Further, different driver models may be used to simulate different driving behaviors of different drivers. Once a virtual vehicle simulation has been performed on a virtual vehicle, one or more parameters of the virtual vehicle may be adjusted and/or the conditions under which the simulation is carried out may be adjusted, and a new simulation may be performed, such that the virtual vehicle simulations may be carried out in parallel and serially as desired.

Training data 114 may subsequently be generated from the performance data collected from the virtual vehicle simulation. The performance data may be analyzed in a first step to determine one or more specific systems or subsystems of the vehicle model that may benefit from a performance optimization. For example, the specific systems or subsystems may be subsystems relating to an energy regeneration of virtual vehicle 113 and/or vehicle 104, and the performance optimization may include increasing an amount of energy regenerated during operation of virtual vehicle 113 and/or vehicle 104. In other embodiments, the specific systems or subsystems may relate to a different aspect of virtual vehicle 113 and/or vehicle 104, where the performance optimization may be based on the different aspect. Data of the performance data relevant to the specific system or subsystem may be extracted and codified to create training data 114, for the purposes of training an ML model 116 of the ML module 117. Generation of training data 114 is described in greater detail below, in reference to FIG. 4.

The ML model 116 may include one or more suitable ML model architectures, such as neural networks, random forest, decision trees, Bayesian networks, etc. The ML model 116 may be trained to generate a variety of desired output. In an example, the ML model 116 may be trained to mimic performance of vehicle 104 under any condition, and thus may be trained to output vehicle sensor and controller data that may be observed given a set of input parameters. In this example, once trained (e.g., once the trained vehicle model 118 is generated), the trained ML model may be a super- or meta-model that collapses each virtual vehicle of the simulation set 112 into a single model and thus demand fewer memory and processing resources. The trained ML model may then be used to optimize vehicle control parameters, such as energy regeneration. In other examples, the ML model 116 may be trained to output more specific/directed information, such as optimal vehicle settings for energy regeneration. In such examples, multiple ML models may be trained, each trained for a specific vehicle control parameter, for example.

Vehicle performance enhancement system 100 may include a fleet management system 120. After training of ML model 116 has concluded, the trained vehicle model 118 may be used to generate a set of parameters of the specific systems or subsystems that may lead to an improved performance of the specific systems or subsystems. For example, the trained vehicle model 118 may be an energy regeneration model, and the set of parameters may optimize an amount of energy regenerated by vehicle 104 during operation. In an embodiment, trained vehicle model 118 may be trained to output a brake torque split value, where the brake torque split value indicates a percentage of brake torque to be applied at wheels of the vehicle produced by friction braking and a corresponding percentage of brake torque to be applied by a motor of the vehicle during regenerative braking. For example, under a first set of driving conditions, where a vehicle is being operated on a first grade, under a first set of weather, road, and temperature conditions, trained vehicle model 118 may output a low brake torque split value, where a smaller portion of the brake torque is generated by friction braking, and a larger portion of the brake torque is generated by the motor (e.g., regenerative braking). Under a second set of driving conditions, where a vehicle is being operated on a second grade, under a second set of weather, road, and temperature conditions, trained vehicle model 118 may output a high brake torque split value, where a larger portion of the brake torque is generated by friction braking, and a smaller portion of the brake torque is generated by the motor. Thus, trained vehicle model 118 may be used to set parameters of vehicle 104 that determine when and how regenerative braking may be applied under different conditions.

In various embodiments, generating the set of parameters leading to the improved performance may include generating a new set of output data from trained vehicle model 118 based on a new set of input data. For example, training data 114 may include a first set of inputs relating to vehicle sensor and/or parameter data, and a second set of inputs relating to factors not sensed at the vehicle. The factors not sensed at the vehicle may include, for example, a grade on which vehicle operation is simulated, or a simulated road load of the vehicle. In one example, a new set of input data may include the first set of inputs, and may not include the second set of inputs. Trained vehicle model 118 may then be used to output braking percentage split values based on vehicle sensor and vehicle parameter data (e.g., the first set of inputs), and not based on factors not sensed at the vehicle (e.g., the second set of inputs). In some embodiments, an expert (e.g., an engineer of the manufacturer) may then analyze the input data and the output data to determine how parameters of the vehicle may be configured to maximize an efficiency of regenerative braking in response to different sets of inputs from vehicle sensors.

In some embodiments, analyzing the input data and the output data may include using additional or secondary modeling techniques to model the input data and the output data and/or a performance of trained vehicle model 118. For example, high dimensional statistical methods (e.g., regressions, k-means, etc.) may be used to identify patterns in the input data and the output data. In some embodiments, trained vehicle model 118 may be retrained with the new input data, using reinforcement learning and/or supervised learning with new generated ground truth data.

The set of parameters that may optimize the amount of energy regenerated by vehicle 104 during operation may be disseminated to various vehicles 104 of fleet 130 via fleet management system 120. In some embodiments, the set of parameters may be disseminated wirelessly (e.g., over wireless network 140). In other embodiments, the set of parameters may be disseminated during manufacture/initial calibration of the vehicles and/or during servicing of the vehicles 104, or in a different manner.

Additionally or alternatively, trained vehicle model 118 may be used to update vehicle model 102. In various embodiments, simulation engine 110 may rerun the virtual vehicle simulation with a new simulation set 112 generated from the updated vehicle model 102, to further enhance performance of virtual vehicles 113. In this way, repeated simulations performed by simulation engine 110 may iteratively improve the performance of virtual vehicles 113 and/or vehicles 104 of fleet 130.

Cloud ecosystem 108 may include one or more processors 122, which may be used by simulation engine 110 and/or ML module 117 to process instructions stored in a memory 124. An advantage of running simulation engine 110 and ML module 117 in cloud ecosystem 108 is that a number of processors 122 and an amount of memory 124 may be assigned on demand, based on operational parameters of simulation engine 110 and/or ML module 117. Additionally, a plurality of processors 122 may execute instructions stored in memory 124 in parallel within a distributed compute environment, which may permit a larger amount of data to be used in simulation and training and result in shorter simulation and training times.

As discussed herein, memory 124 may include any non-transitory computer readable medium in which instructions are stored. For the purposes of this disclosure, the term “non-transitory computer readable medium” is expressly defined to include any type of computer readable storage, which in various embodiments may include a non-transitory computer readable medium such as a flash memory, a read only memory (ROM), a random access memory (RAM), a cache, or any other storage media (e.g., a tangible medium) in which information is stored for any duration (e.g., for extended period time periods, permanently, brief instances, for temporarily buffering, and/or for caching of the information). Computer memory of computer readable storage mediums as referenced herein may include volatile and non-volatile or removable and non-removable media for a storage of electronic-formatted information such as computer readable program instructions or modules of computer readable program instructions, data, and the like that may be stand-alone or as part of a computing device. Examples of computer memory may include any other medium which can be used to store the desired electronic format of information and which can be accessed by the processor or processors or at least a portion of a computing device. Various methods and systems disclosed herein may be implemented using instructions (e.g., programming instructions, coded instructions, executable instructions, computer readable instructions, and the like) stored in a non-transitory computer readable medium.

Thus, by collecting performance data from a first plurality of real vehicles and using the performance data to generate a vehicle model of the real vehicles, and subsequently simulating the operation of a plurality of virtual vehicles based on the vehicle model, an amount of performance data of the real vehicles may be increased. The increased amount of performance data may then be used to create and/or train a high dimensional statistical model, such as an ML model, to output parameter settings that may optimize the performance of the real vehicles.

As described above, in various embodiments, the vehicle model may be a computer model comprising various sub-models. FIGS. 2A and 2B together may represent an exemplary vehicle model 102 representing a battery-electric vehicle (BEV), where FIG. 2A shows a first portion of the exemplary vehicle model 102 including a driver model and a vehicle controller model, and FIG. 2B shows a second portion of the exemplary vehicle model 102 including a powertrain model and a vehicle model.

Referring now to FIG. 2A, a schematic representation of a first portion 200 of an exemplary vehicle model (e.g., vehicle model 102) of a vehicle is shown. First portion 200 may include a driver model 230 and a vehicle controller model 202, each of which may receive various inputs and generate various outputs. In some cases, one or more outputs of driver model 230 and vehicle controller model 202 may be inputs into driver model 230, vehicle controller model 202, or a different sub-model of the vehicle model not shown in FIG. 2A.

Driver model 230 may model inputs into the vehicle model, such as, for example, commands made by a simulated operator of the vehicle. Driver model 230 may receive as input a speed 232. Speed 232 may be a desired speed, or a desired change in speed of the vehicle commanded by a simulated driver of the vehicle. Driver model 230 may receive as input a grade 233 (e.g., road grade), for example, expressed as a percentage. Based on vehicle speed 232 and grade 233 over a duration (e.g., 1 second, driver model 230 may generate a torque demand 210. Driver model 230 may also receive as input a glider output 234, where the glider output 234 is an output of the vehicle model. The glider output 234 may be a speed, or a change of speed of the vehicle after a first flow of data through the vehicle model. The glider output 234 is described in greater detail below in reference to FIG. 2B.

Torque demand 210 may be an input into vehicle controller model 202. Vehicle controller model 202 may receive additional inputs, such as a transmission output 212, a motor output 214, an auxiliary load output 216, and a battery/fuel cell output 218. Transmission output 212 and motor output 214 may be outputs of a transmission model and a motor model, respectively, as described in greater detail below in reference to FIG. 2B.

Based on the inputs (e.g., torque demand 210, transmission output 212, motor output 214, auxiliary load output 216, and battery/fuel cell output 218), vehicle controller model 202 may generate a plurality of outputs, including a gear selection 220 (e.g., to be inputted into a transmission model of the vehicle model), a motor control 222 (e.g., to be inputted into a motor model of the vehicle model), a brake control 224 (e.g., to be inputted into a driveline model of the vehicle model), and an energy management output 226. Energy management output 226 may be a control signal inputted into a battery/fuel cell 240 and at least in some examples may represent an amount of recovered energy to be stored in battery/fuel cell 240.

Battery/fuel cell 240 may output battery/fuel cell output 218, which may be inputted into vehicle controller model 202, based on energy management output 226. An additional input into battery/fuel cell 240 may be a thermal system output 251 of a thermal system 250, based on battery/fuel cell output 218. The thermal system output 251 may also be an input into an auxiliary load element 252, which may generate the auxiliary load output 216. The auxiliary load output may be inputted into vehicle controller model 202. Thus, inputs and outputs of vehicle controller model 202, battery/fuel cell 240, thermal system 250, and auxiliary load element 252 may comprise an energy regeneration feedback loop 254.

An amount of energy regenerated by the vehicle may depend on parameters of energy regeneration feedback loop 254. In other words, by adjusting parameters (e.g., characteristics) of battery/fuel cell 240, auxiliary load 252, thermal system 250, and vehicle controller model 202, a desired energy management output 226, battery/fuel cell output 218, thermal system output 251, and auxiliary load output 216 may be achieved that maximizes the amount of energy regenerated. Determining a set of desired parameters of battery/fuel cell 240, auxiliary load 252, thermal system 250, and vehicle controller model 202 may be accomplished by simulating vehicle operation using the vehicle model a number of times, and collecting energy regeneration performance data at different parameter settings over different drive cycles. As described herein, a ML model may then be used to analyze the combinations of settings with respect to a desired performance. For example, parameter settings resulting in the desired performance may be used as ground truth data, and parameter settings that do not result in the desired performance may be used as training input data. As described in greater detail in reference to FIG. 3, vehicle operation using the vehicle model may be simulated for a plurality of virtual vehicles over a plurality of drive cycles and driving conditions to ensure training data robustness.

Referring now to FIG. 2B, a schematic representation of a second portion 260 of a vehicle model (e.g., vehicle model 102) of a vehicle is shown. Second portion 260 may include a powertrain model 262 and a vehicle model 270, each of which may receive various inputs and generate various outputs. In some cases, one or more outputs of powertrain model 262 and vehicle model 270 may be inputs into vehicle model 270 and powertrain model 262, respectively, driver model 230, and/or vehicle controller model 202 of FIG. 2A. It should be appreciated that while in the depicted vehicle model the vehicle is a battery-electric vehicle (BEV), in other embodiments the vehicle may not be a BEV and the vehicle model may include additional and/or other components, such as an internal combustion engine (ICE).

Powertrain model 262 may represent various components in an electrified powertrain of the vehicle, including electric machines, gear boxes, final drives, high voltage / low voltage (HV/LV) batteries, direct current to direct current (DC-DC) converters, and the like. In various embodiments, powertrain model 262 may be divided into one or more subsystems, based on data published by relevant component teams. For example, powertrain model 262 may include a motor model 264, which may model an electric motor of the vehicle; a transmission model 266, which may model a transmission of the vehicle; and a driveline model 268, which may model a torque supplied to wheels of the vehicle based on the electric motor, the transmission, and an application of one or more brakes of the vehicle. In various embodiments, powertrain model 262 may receive input from vehicle controller model 202 of FIG. 2A. Specifically, motor control 222 outputted by vehicle controller model 202 may be an input into motor model 264; gear selection 220 outputted by vehicle controller model 202 may be an input into transmission model 266; and brake control 224 outputted by vehicle controller model 202 may be an input into driveline model 268.

Battery/fuel cell output 218 may be an additional input into motor model 264, and based on battery/fuel cell output 218, output from transmission model 266, output from driveline model 268, and motor control 222, motor model 264 may generate an output that is received as an input into transmission model 266. Based on the output of motor model 264, the output from driveline model 268, and gear selection 220, transmission model 266 may generate an output that is received as input into the driveline model 268. Based on the output of transmission model 266 and brake control 224, driveline model 268 may generate an output that is received as input into vehicle model 270.

Vehicle model 270 may take characteristics of the vehicle such as tire size, frontal drag, vehicle mass, and the like, and model various road loads acting on the vehicle at different points in a drive cycle or maneuver. The characteristics may be included in vehicle model 270 as parameters that may be configured, for example, based on a configuration file associated with the vehicle model, as described below in reference to FIG. 2C. Vehicle model 270 may generate a glider output 234, which may comprise operational state data of the vehicle as a result of a flow of data through the vehicle model. For example, glider output 234 may include a speed of the vehicle, a selected gear of the vehicle, a state of one or more brakes of the vehicle, and the like. Glider output 234 may be inputted back into driver model 230, as described above in reference to FIG. 2A, to complete a global feedback loop. Glider output 234 may also be provided as an additional input into transmission model 266 and/or driveline model 268 in a powertrain feedback loop 272 with powertrain model 262.

As explained previously, vehicle model 102 may be generated based on historical and/or statistical data (e.g., vehicle operational data and instrumentation data) collected from one or more actual vehicles operated using a dynamometer at a lab of a manufacturer of the one or more vehicles. The vehicle operational data collected to generate the vehicle model 102 may be obtained from a variety of sensors positioned on the one or more vehicles. The sensors may include but are not limited to an accelerator pedal position sensor, vehicle speed sensor, steering wheel position sensor, motor sensors (e.g., motor speed, motor torque, motor power), battery sensors (e.g., battery state of charge, battery temperature, battery output), transmission sensors (e.g., input shaft speed, output shaft speed), suspension system sensors, wheel speed sensors, braking sensors (e.g., brake pedal position, friction brake torque), auxiliary load sensors (e.g., sensors configured to measure an electric load placed by one or more auxiliary loads such as the vehicle HVAC system and vehicle cabin electric loads), and environment condition sensors (e.g., ambient temperature, ambient pressure, ambient humidity). The instrumentation data may include data generated at the dynamometer, such as road load and road grade, as well as output from sensors positioned on the one or more vehicles that may not be present on typical deployed vehicles. Further, vehicle operational data may be obtained from a vehicle controller of each of the one or more vehicles. The vehicle operational data obtained from the vehicle controller(s) may include but is not limited to commanded vehicle operating parameters (e.g., commanded motor torque, commanded brake torque, commanded regenerative braking torque and/or commanded regenerative braking torque/friction braking torque ratio) and operator inputs (e.g., activation of cabin heating or cooling, transmission gear shifts).

FIG. 2C shows how a vehicle model 284 may be used by elements of a cloud ecosystem 280, where vehicle model 284 may be a non-limiting embodiment of the vehicle model of FIGS. 2A and 2B and/or vehicle model 102 of FIG. 1, and cloud ecosystem 280 may be a non-limiting embodiment of cloud ecosystem 108 of FIG. 1. As described above in reference to FIG. 1, vehicle model 284 may be uploaded to cloud ecosystem 280 to be used by a simulation engine 295 (e.g., simulation engine 110) to generate a plurality of virtual vehicles for data gathering purposes.

Cloud ecosystem 280 may include a processor 281, a simulation engine 295, vehicle model software 282, and a memory 292. In various embodiments, vehicle model 284 may be a computer model embodied in vehicle model software 282. Vehicle model software 282 may additionally include a configuration file 286 and a user interface (UI) 288.

Various parameters of vehicle model 284 may be defined in configuration file 286. For example, configuration file 286 may include settings for vehicle characteristics, such as a type of a vehicle, an age or a number of miles driven by the vehicle, a size of the vehicle, a weight of the vehicle, and the like. Configuration file 286 may include settings for drive cycle and/or driving route including length, duration, grade, and/or other characteristics. Configuration file 286 may further establish maximum or minimum settings for operation of the modeled vehicle, such as a maximum speed, minimum turning radius, minimum braking distance, and the like. Configuration file 286 may include settings for weather conditions, road conditions, time of day, and/or other characteristics of an environment of the modeled vehicle for an assigned drive cycle. It should be appreciated that the examples provided herein are for illustrative purposes, and additional or different settings may be included in configuration file 286 without departing from the scope of this disclosure.

During creation of vehicle model 284, a user 290 (e.g., a software engineer in a laboratory of a vehicle manufacturer) may configure the parameters of vehicle model 284 by adjusting one or more settings of configuration file 286. For example, user 290 may open configuration file 286 on a display device (e.g., a monitor) and manually enter in settings of configuration file 286 via a keyboard or another input device. Alternatively, user 290 may adjust the one or more settings of configuration file 286 via UI 288, for example, by interacting with virtual controls of UI 288, or dialog boxes, wizards, and/or similar graphical user elements.

After vehicle model 284 has been configured by user 290, user 290 may interact with vehicle model software 282 to run a simulation of vehicle model 284, via UI 288, based on the settings of configuration file 286. During the simulation, various inputs and outputs of sub-models and/or subsystems of vehicle model 284 may be generated, which may be saved as model output data 294 of memory 292. The sub-models and/or subsystems of vehicle model 284 may include driver model 230 and vehicle controller model 202 of FIG. 2A, and powertrain model 262 and vehicle model 270 of FIG. 2B. During testing of vehicle model 284, various configurations may be tested and analyzed to determine a suitable set of initial configuration parameters for simulation on a larger scale, within cloud ecosystem 280.

Vehicle model 284 may be uploaded to cloud ecosystem 280 bundled within vehicle model software 282. Within cloud ecosystem 280, simulation engine 295 may interact with vehicle model 284 via configuration file 286. For example, simulation engine 295 may include an instance management module 296 and a configuration generator 297. Instance management module 296 may be used to generate and track a plurality of virtual vehicles, each virtual vehicle based on vehicle model 284. Tracking the plurality of virtual vehicles may include tracking model output data 294 for each virtual vehicle instance (e.g., each time a simulation with a virtual vehicle is performed). Configuration generator 297 may be used to define parameters for each virtual vehicle instance. For example, configuration generator 297 may generate a first set of settings for a first virtual vehicle instance, a second set of settings for a second virtual vehicle instance, a third set of settings for a third virtual vehicle instance, and so forth. In various embodiments, the first set of settings, the second set of settings, and the third set of settings, and subsequent sets of settings may be randomly selected within pre-established ranges based on one or more algorithms of simulation engine 295.

As an example, the first set of settings for the first virtual vehicle instance generated by configuration generator 297 may include a first set of equation parameters and weights for a regenerative braking/friction braking torque dynamic equation (also referred to as braking dynamic equation) that may be applied each time a braking request is applied during a simulation of the first virtual vehicle instance. The braking dynamic equation may dictate how much braking torque is applied via regenerative braking and how much braking torque is applied via friction braking during a given braking event (e.g., the brake torque split). The braking dynamic equation may include a plurality of equation parameters that may be assigned various weights. In some examples, the equation parameters may represent vehicle parameters, such as vehicle speed, vehicle weight, brake pedal position, battery conditions (e.g., state of charge), and various road conditions (e.g., that impact friction, such as whether the road is wet, the road is covered in snow or ice, etc.), in order to determine a brake torque split that will cause the vehicle to slow or stop as requested by the operator (e.g., due to the application of the brake pedal) while also recovering vehicle kinetic energy and converting the energy to electricity that can be stored in the battery. However, an ideal braking dynamic equation that should applied for each braking event may be impossible for a human to manually determine given that the number of equation parameters that could be included in the braking dynamic equation is relatively large and thus the number of possible combinations of parameters and weights is high.

Accordingly, the virtual vehicles may be assigned various different settings and the data collected from the simulations may be used to train a ML model to determine which equation parameters and/or weights to include in the braking dynamic equation, which may also change as conditions change. Thus, the first set of parameters and weights for the first virtual vehicle instance may include some or all of the possible equation parameters and respective weights assigned to each parameter. The second set of settings for the second virtual vehicle instance may include a different, second set of equation parameters and weights, the third set of settings for the third virtual vehicle instance may include a still further different, third set of equation parameters and weights, and so forth. In another examples, the data collected from the simulations may be used to train a super ML model that mimics a plurality of real vehicles under a plurality of different conditions, as explained above, and the super ML model, once trained, may be used to generate training data for training a specialized ML model to determine which equation parameters and/or weights to include in the dynamic braking equation.

The model output data 294 for each vehicle instance may include output data that can be entered as input to the ML model to determine the ideal braking dynamic equation as explained above. As such, the model output data 294 may include, for each simulated braking event, the brake torque split that was applied, the duration of the simulated braking event, the vehicle speed during the braking event (e.g., vehicle deceleration), and so forth. Further, while regenerative braking is presented herein as an example vehicle control parameter that may be adjusted and/or optimized according to the model output data 294 and subsequently trained ML model, other vehicle control parameters may be adjusted or optimized in a similar manner.

Referring now to FIG. 3, an exemplary method 300 is shown for training an ML model to increase an efficiency of energy regeneration of a vehicle based on simulated performance data, where the simulated performance data is generated and collected by a cloud-based simulation engine. While the ML model of method 300 is trained on data specifically relating to energy regeneration, it should be appreciated that in other embodiments the ML model may be trained using different performance data to increase an efficiency of a different subsystem or component of the vehicle. One or more steps of method 300 may be executed by one or more processors running in a cloud ecosystem, such as processors 122 of cloud ecosystem 108 of FIG. 1, based on instructions stored in a memory of a cloud ecosystem, such as memory 124 of cloud ecosystem 108 of FIG. 1. The one or more processors and memory may be accessed, for example, by one or more software programs including a simulation engine, such as simulation engine 110, and an ML module, such as ML module 117.

Method 300 begins at 302, where method 300 includes receiving a vehicle model of a vehicle (e.g., vehicle model 102). As described above in reference to FIG. 1, the vehicle model may be a computer model stored in software that may be uploaded to the cloud ecosystem, for example, from a laboratory where the vehicle model is generated. The vehicle model may be built to mimic the behavior of an actual vehicle running on a Dynamometer (Dyno). For example, road, weather, and/or mapping conditions maybe simulated that are similar to real situations encountered by a real vehicle (e.g., on which the vehicle model is based). Thus, when the vehicle model is executed, it may act like an actual vehicle with similar characteristics from a components and behavior perspective, and may produce the same or substantially similar outputs in terms of battery consumption, energy consumption by different components, and the like.

At 304, method 300 includes developing a virtual cloud vehicle based on the vehicle model, as well as other vehicle characteristics. In various embodiments, developing the virtual cloud vehicle may include establishing a virtual vehicle structure designed to accommodate replication within a simulation environment. For example, in addition to the vehicle model software including the vehicle model and a configuration file (e.g., configuration file 286 of FIG. 2C), each virtual cloud vehicle may be assigned tracking data, pointers to allocated memory where output data may be stored, triggers for notifications or actions if a desired or undesired state is achieved, and the like.

At 306, method 300 includes using a simulation engine to generate a simulation set of a plurality of virtual cloud vehicles. For example, the simulation set may include thousands of virtual vehicles, or tens of thousands of virtual vehicles, or hundreds of thousands of virtual vehicles, or millions of virtual vehicles. A size of the simulation set may vary depending, for example, on a type of performance data that is desired to be collected (e.g., data of a certain vehicle type, or data of a certain system of the vehicle, and so forth). As described above in reference to simulation engine 295 of FIG. 2C, the simulation engine may include an instance management module (e.g., instance management module 296), which may generate and track each virtual vehicle of the plurality of virtual cloud vehicles. For example, for each virtual vehicle created, an amount of memory (e.g., memory 124 of FIG. 1) may be requested from the cloud ecosystem to store the instance, and to collect performance data of the virtual vehicle, an amount of random access memory (RAM) and an amount of processing power may be requested from the cloud ecosystem to cover the simulation of the virtual vehicle. The instance management module may also store tracking and/or monitoring data that may allow the simulation engine to collect, group, isolate, and/or aggregate performance data of each virtual vehicle.

For generating virtual vehicles that each include a configured vehicle model, the instance management module may also use a configuration generator (e.g., configuration generator 297 of FIG. 2C) to establish differences in settings and parameters of the vehicle models of each virtual vehicle. For example, based on an algorithm of the simulation engine, the configuration generator may determine what parameter settings will be used for each virtual vehicle, and define the parameter settings in the configuration file of the vehicle model software associated with the virtual vehicle. By varying the parameter settings across virtual vehicles of the simulation set, performance data may be generated and collected for a variety of different types of vehicles, vehicles with different characteristics (e.g., age, weight, size, etc.), and/or different route, traffic, and/or environmental conditions, thereby ensuring that the performance data reflects a range of real situations encountered by real vehicles.

At 308, method 300 includes running the simulation engine on the simulation set of vehicles. Running the simulation engine on the simulation set of vehicles may include initiating an operation of each virtual vehicle of the simulation set, based on an assigned drive cycle or route and a defined vehicle model configuration, in accordance with memory and processing power allocated by the cloud ecosystem. While the simulation is running on the simulation set, the simulation engine may monitor the performance of the virtual vehicles collectively and/or individually.

At 310, running the simulation engine on the simulation set of vehicles includes collecting performance data relating to energy regeneration. The performance data relating to energy regeneration may include, for example, inputs, outputs, and parameter settings of components of an energy regeneration system of the vehicle model. For example, the performance data relating to energy regeneration may include parameter settings of battery/fuel cell 240, auxiliary load 252, thermal system 250, and vehicle controller model 202 of FIG. 2A collected at various times during a drive cycle, and auxiliary load output 216, battery/fuel cell output 218, thermal system output 251, and energy management output 226 of FIG. 2A. In some examples, the performance data relating to energy regeneration may include the brake torque split that was applied during braking events and other related data, such as vehicle speed during the braking event, as explained above.

At 312, method 300 includes using the collected simulation data to create training data for training an ML energy regeneration model. Generating the training data may entail selecting specific performance data and rejecting other performance data, and is described in greater detail below in reference to FIG. 4.

At 314, method 300 includes training the ML energy regeneration model to increase energy regeneration of virtual cloud vehicles, using the training data set. Specifically, increasing the energy regeneration of the virtual cloud vehicles may include determining a set of desired parameters for configuring components of the energy regeneration system of the vehicle model that maximize energy regeneration, which may correspond to physical components of an energy regeneration system of the real vehicles upon which the vehicle model is based. In various embodiments, the ML energy regeneration model may be trained to output the desired parameters for various combinations of input data, for example, using backpropagation based on a loss function that penalizes poor energy regeneration. The various combinations of input data may include, for example, speeds of different classes of vehicles on different grades, combined with specific road or climatic conditions, and the like.

As an example, the ML energy regeneration model may be trained to determine equation parameters and weights for a braking dynamic equation that dictates a brake torque split that is to be applied during a braking event. In some examples, the ML energy regeneration model may be trained to determine the equation parameters and weights in a condition- or mode-specific manner, such that the ML energy regeneration model may determine different braking dynamic equations for different vehicle or environmental conditions.

At 315, method 300 includes retraining the ML energy regeneration model and/or modeling input/output data of a trained ML energy regeneration model (e.g., trained vehicle model 118 of FIG. 1) to determine a set of ideal parameters for the energy regeneration system of the vehicle and/or vehicle model. In various embodiments, the input data used to train the ML energy regeneration model may include data not available at a real vehicle (e.g., vehicle 104 of FIG. 1) during operation, which may include the instrumentation data described previously. For example, the training input data may include a grade that a vehicle is being operated on during a virtual drive cycle, or an estimated road load of the vehicle. In some embodiments, the trained ML energy regeneration model may be retrained on a subset of the training data, where the input data not available at the real vehicle has been eliminated from the subset. By eliminating data unavailable to the real vehicle during operation, the trained ML energy regeneration model may be retrained to learn to predict an ideal set of parameters for the energy regeneration system based on sensor data received at a real vehicle during operation.

Additionally and/or alternatively, input and output data of the trained ML energy regeneration model or the retrained ML energy regeneration model may be further modeled using additional and/or other modeling methods and techniques. For example, a second ML energy regeneration model may be trained using training data generated using the trained ML energy regeneration model, or one or more statistical methods may be applied to data generated by the trained or retrained ML energy regeneration model, for example, to identify input/output data patterns of the trained or retrained ML energy regeneration model. The input/output data patterns may also be analyzed by human experts, such as an engineering team of a manufacturer of the vehicle. By analyzing the input/output data patterns, a set of suitable or ideal parameters of the energy regeneration system of the real vehicle may be identified that may increase an efficiency of the energy regeneration system under a range of driving conditions sensed at the vehicle.

At 316, method 300 includes setting vehicle control unit (VCU) parameters of one or more real vehicles based on an analysis an output of the trained or retrained ML energy regeneration model, as described above. In some examples, setting the VCU parameters may include updating existing VCU parameters, such as by sending updates to the one or more real vehicles using over-the-air (OTA) capabilities (e.g., via a wireless network such as network 140). In some examples, setting the VCU parameters may include setting initial VCU parameters during manufacture of the one or more real vehicles. In various embodiments, VCU parameters of the vehicles may be updated by a fleet management system, such as the fleet management system 120 described above in reference to FIG. 1. For example, the ML energy regeneration model may determine a braking dynamic equation that includes different equation parameters and/or weights than a braking dynamic equation currently implemented in deployed vehicles. In such examples, an update to the braking dynamic equation may be sent to the deployed vehicles and the braking dynamic equation stored in memory of the VCUs of the deployed vehicles may be updated to the new braking dynamic equation. In some examples, once trained and validated, the ML energy regeneration model itself may be sent to each deployed vehicle, where the ML energy regeneration model may be used during vehicle operation to determine, based on current vehicle operating conditions, whether regenerative braking should be performed, the brake torque split that is to be applied, a regenerative braking torque threshold/limit, or other suitable parameter.

At 318, method 300 includes updating parameters of the vehicle model of the vehicle based on the analysis of the trained or retrained ML energy regeneration model. In other words, determinations of parameter settings that may maximize energy regeneration in physical vehicles may be used to inform an improved general configuration of the vehicle model for future simulations, and/or a logic of the vehicle model and/or vehicle model software. For example, if it is determined from the trained ML energy regeneration model that a set of vehicle subsystem parameters is correlated with an increased energy regeneration during a first driving condition, and the set of vehicle subsystem parameters is correlated with a decreased energy regeneration during a second driving condition, the logic of the vehicle model and/or vehicle model software may be adjusted to adopt the set of vehicle subsystem parameters when the first driving condition occurs, and not to adopt the set of parameters when the second driving condition occurs, or to adopt a second set of parameters correlated with an increased energy regeneration during the second driving condition. In this way, an efficiency and/or an accuracy of the vehicle model may be continually increased based on an evolution of the trained ML energy regeneration model over successive virtual simulations. As a specific example, a first iteration of the trained ML energy regeneration model may identify a combination of equation parameters for the braking dynamic equation under a first set of conditions. The vehicle model may be updated to include a braking dynamic equation using that combination of equation parameters, and then further virtual vehicle simulations may be performed to collect performance data usable to train the ML energy regeneration model to determine specific weights to apply to each equation parameter and/or to determine a combination of equation parameters for the braking dynamic equation under a second set of conditions.

Similarly, at 320, method 300 includes updating simulation parameters of the simulation engine for a subsequent simulation based on the analysis of the trained or retrained ML energy regeneration model. For example, a first ML energy regeneration model may be trained on performance data from a first virtual vehicle simulation. The first vehicle simulation may be run with a first number of virtual vehicles, over a first range of different driving conditions. As a result of the performance data from the first virtual vehicle simulation, the first trained ML energy regeneration model may be used to increase an amount of energy regenerated by a vehicle by a first percentage. However, the first trained ML energy regeneration model may perform well at increasing regenerated energy during a first driving condition, but poorly at increasing regenerated energy during a second driving condition. To further increase the amount of energy regenerated by a vehicle to a second, higher percentage, a second set of performance data may be collected from a second virtual vehicle simulation, to be used to train a second ML energy regeneration model. The second vehicle simulation may be run with a second, smaller number of virtual vehicles, over a second, smaller range of driving conditions (e.g., similar to the second driving condition), as the second ML energy regeneration model may be focused on increasing energy regeneration in a smaller set of circumstances. Thus, over successive simulations, different simulation parameters may be used to iteratively refine the vehicle model over a wide range of conditions. Method 300 ends.

Referring now to FIG. 4, an exemplary method 400 is shown for generating training data, from a larger set of performance data collected during a virtual vehicle simulation, for training an ML model to increase an energy regeneration of a vehicle. The virtual vehicle simulation may include a large number of virtual vehicles operating under a wide range of conditions, as described above. In an embodiment, one or more steps of method 400 may be executed by one or more processors running in a cloud ecosystem, such as processors 122 of cloud ecosystem 108 of FIG. 1, based on instructions stored in a memory of a cloud ecosystem, such as memory 124 of cloud ecosystem 108 of FIG. 1. The one or more processors and memory may be accessed, for example, by an ML module, such as ML module 117.

In some embodiments, some of the performance data collected during the virtual vehicle simulation may not be relevant to energy regeneration, and may therefore not be useful for training the ML model. In other embodiments, the performance data relevant to energy regeneration may not be clearly established, and most or all of the performance data may be used for training a larger ML model. A desired size of the ML model, an amount of performance data collected, and an amount of training data used to train the ML model may vary in different implementations of the virtual vehicle simulation.

Method 400 begins at 402, where method 400 includes extracting a plurality of regeneration events from the performance data, each regeneration event including data relevant to energy regeneration. For the purpose of this disclosure, a regeneration event may be an instance in which energy is generated at a virtual vehicle (also referred to herein as the vehicle) for an increment of time. The increment of time may be a second, or ⅒ of a second, or a different duration depending on the simulation. For example, if the vehicle is being operated down a grade and pressure is being applied to brakes of the vehicle for 10 seconds, during which energy is generated at the vehicle, 10 one-second regeneration events may be extracted, or 100 ⅒ second regeneration events may be extracted. Alternatively, if the vehicle is being operated up a grade and no energy is being generated at the vehicle, no regeneration events may be extracted from the performance data during time increments when the vehicle is operating up the grade. By extracting the regeneration events, performance data relevant to energy regeneration may be included in the training data, and performance data not relevant to energy regeneration may not be included in the training data. However, in some embodiments, performance data relevant to energy regeneration may be collected during select periods where no regeneration events were occurring, such as when the vehicle was moving without being propelled by the motor but a regeneration event was not commanded.

Further, in some embodiments, regeneration events of different time increments may be extracted, to identify patterns in performance data relating to energy regeneration that may occur over different periods of time. For example, a first set of regeneration events may be extracted from the performance data at a first time increment; a second set of regeneration events may be extracted from the performance data at a second time increment, where the second time increment is longer than the first time increment, and may include a plurality of first time increments; a third set of regeneration events may be extracted from the performance data at a third time increment, where the third time increment is longer than the first and second time increments, and may include a plurality of first and second time increments; and so on. During training of the ML model, data from regeneration events of different time increments may be inputted into the ML model during different stages of training, or during a same stage of training, inputted concurrently into a same input layer or inputted into different layers of the ML model.

At 404, method 400 includes associating operational state data of the vehicle with each regeneration event. For each regeneration event, state data of components of an energy regeneration subsystem of the vehicle (e.g., the vehicle controller model 202, battery/fuel cell 240, thermal system 250, and auxiliary load 252 described above in reference to FIG. 2A) during or immediately prior to the regeneration event may be extracted from the performance data and associated with the regeneration event. The state data may include, for example, parameter settings of the components, and/or inputs and outputs of the components leading up to or occurring at the time of the regeneration event.

At 406, method 400 includes associating drive cycle and/or route data corresponding to the time increment of the regeneration event with the regeneration event, as well as contextual data relevant to the regeneration event. The contextual data may include, for example, road, weather, and/or driving conditions at the time of the regeneration event, or different contextual information. For example, a first regeneration event of a first vehicle may occur at a time when the first vehicle is operating in a cold, dry climate with low traffic and smooth roads; a second regeneration event of a second vehicle may occur at a time when the second vehicle is operating in a hot, wet climate with high traffic and roads in poor condition; a third regeneration event of a third vehicle may occur at a time when the third vehicle is operating in a hot, dry climate with low traffic; and so on. During training, the contextual data may be used by the ML model to help predict how operational parameters of the components of the energy regeneration system of the vehicle may be configured for different types of environments and driving conditions.

At 408, method 400 includes associating an energy regeneration rating with each regeneration event. If an amount of energy generated during the regeneration event is high, given the drive cycle and contextual data, a high rating may be assigned to the regeneration event. If an amount of energy generated during the regeneration event is low, given the drive cycle and contextual data, a low rating may be assigned to the regeneration event.

Whether an amount of energy generated is determined to be high or low may depend on benchmark data collected under laboratory conditions with a real vehicle, for example, being operated on a dyno. For example, under laboratory conditions it may be determined that when the vehicle is operated on a grade and brakes of the vehicle are applied in a first manner, a first, large amount of energy may be generated at the vehicle. If the brakes are applied in a second manner on the grade, a second, lesser amount of energy may be generated at the vehicle. As a result, the first manner of applying the brakes may be established as a benchmark for optimal energy regeneration. In the performance data generated during the simulation, if the vehicle is being operated on a similar grade during a regeneration event and the performance data indicates that the amount of energy generated is similar to the first, large amount of energy (e.g., the benchmark), a high rating may be assigned to the regeneration event. Alternatively, if the vehicle is being operated on the similar grade and the performance data indicates that the amount of energy generated is less than the benchmark, a proportionally lower rating may be assigned to the regeneration event. By assigning a rating to the regeneration event, ground truth data may be acquired, where the ground truth data may indicate a desired or target set of parameters for an associated grade, speed, and set of driving conditions.

At 410, method 400 includes creating a plurality of training data pairs from the regeneration events. In various embodiments, the ML model may be trained using supervised learning, where the ML model is trained using data pairs comprising input data and target (e.g., ground truth) data, and the ML model is trained to predict the target data from the input data. A training data pair may be generated from a regeneration event. For example, the state data (e.g., parameter settings, inputs, and outputs of energy regeneration system components) and the contextual data (e.g., road, environmental, and driving conditions) may be used as input data of the training data pair, and the energy regeneration rating of the regeneration event may be used as the target or ground truth data. During training, a backpropagation algorithm with a loss function may be used to train the ML model to predict the energy regeneration rating from the input data.

In other embodiments, the ML model may be trained using unsupervised learning. During unsupervised learning, the ML model may not be trained to predict the energy regeneration rating based on input/target training pairs. The energy regeneration rating may be included in the input data, and no ground truth data may be provided. When the input data is inputted into the ML model, one or more different algorithms may be used to identify patterns in the input data, or organize the input data into groups. The patterns or groups may be subsequently analyzed to determine desired parameter settings of the energy regeneration system components for different drive cycles and driving conditions.

In still further embodiments, the ML model may be trained using reinforcement learning. During reinforcement learning, the ML model may be trained to learn an optimal policy (such as a brake torque split) that maximizes a reward (e.g., energy regeneration) while minimizing one or more penalties (e.g., increased stoppage distance). Once trained with reinforcement learning, the ML model may be configured to receive a set of vehicle inputs (e.g., speed, brake pedal position, vehicle weight, road conditions) and output a brake torque split that maximizes energy regeneration without compromising vehicle deceleration. The output from the ML model may then be used to develop a braking dynamic equation or populate a look-up table that may be sent to deployed vehicles.

As explained previously, the vehicle model that is used to generate the virtual vehicles is built based on vehicle data and instrumentation data (e.g., sensor data, controller data). In some examples, the vehicle and instrumentation data that is collected to build the vehicle model may represent a larger amount of monitored or sensed parameters than the parameters that are sensed and monitored in deployed vehicles. As such, the ML model(s) described herein may be deployed in a state where the ML models take a first number of parameters as inputs, where each input parameter is a parameter that can be sensed or inferred from a deployed vehicle. In contrast, the training data used to train the ML models may include a second number of parameters that is larger than the first number of parameters, as more performance data may be available using the virtual vehicles than using actual deployed vehicles.

While FIGS. 3 and 4 have been described herein as relating to training a ML model specific to energy regeneration, it is to be appreciated that the platform described herein (and specifically, the training data collected from the simulations of the virtual vehicles) may be used to train a super ML model that is trained to map any combination of inputs (e.g., accelerator pedal position, brake pedal position, vehicle speed, road/environment conditions, motor torque, battery state of charge) to a respective set of outputs (e.g., commanded motor torque, subsequent vehicle speed, brake torque split). The super ML model may then be used to generate training data for training a subsequent ML model with a specific goal (e.g., to map a selected group of inputs to optimal brake torque split). In other examples, once trained, the super ML model may be used during an inference stage to identify an optimized output (e.g., brake torque split that maximizes energy regeneration without compromising vehicle stopping distance) given a set of input parameters (which may mimic input parameters available at a deployed vehicle).

Thus, systems and methods are provided for increasing an amount of operational data of a vehicle that may be collected for analytics purposes, by creating virtual vehicles based on a vehicle model of the vehicle. The virtual vehicles may be created in a cloud, where sufficient memory and parallel processing resources may be allocated on demand to support a desired number of vehicles of a simulation set. Operation of the virtual vehicles may be simulated over a variety of different drive cycles, routes, and/or driving/environmental conditions to collect a robust dataset of performance data with a desired distribution. The dataset may then be used to train a ML model to identify and/or predict a configuration of parameter settings of components of one or more vehicle systems to increase an efficiency of the vehicle. By using simulated performance data rather than data generated by real vehicles, an amount of data available for training the ML model may be increased, while reducing an amount of time spent collecting data. The increased amount of data may result in more robust and accurate ML models, and the reduced amount of time taken to generate the data may shorten a time and reduce a cost of developing and deploying performance enhancements of the vehicle.

The technical effect of training a ML model to increase an efficiency of a vehicle with simulated performance data based on a vehicle model of a vehicle rather than performance data of vehicles in operation in the real world is that a greater amount of data covering a wider variety of driving conditions may be collected in a shorter time frame.

The disclosure also provides support for a method, comprising: building a vehicle model based on sensor data collected from one or more training vehicles, generating a simulation set of virtual vehicles based on the vehicle model, executing a simulation of each of the simulation set of vehicles a plurality of instances, each instance executed with different simulation vehicle operating parameters, obtaining simulation vehicle data from each of the simulation set of vehicles at each instance, training a machine learning model with the simulation vehicle data, and setting one or more parameters of one or more real vehicles based on output from the trained machine learning model. In a first example of the method, building the vehicle model based on sensor data collected from one or more training vehicles comprises building the vehicle model based on sensor data from a first number of sensors each installed on the one or more training vehicles, and wherein the machine learning model is trained to take, as input, sensor data from a second number of sensors installed on the one or more real vehicles. In a second example of the method, optionally including the first example, updating the one or more real vehicles includes storing, in memory of the one or more real vehicles, the trained machine learning model. In a third example of the method, optionally including one or both of the first and second examples, setting one or more parameters of the one or more real vehicles includes updating one or more calibratable vehicle parameters of each of the one or more real vehicles based on the output from the machine learning model. In a fourth example of the method, optionally including one or more or each of the first through third examples, updating the one or more calibratable vehicle parameters comprises updating a braking dynamic equation configured to determine a brake torque split to apply during a braking event, the brake torque split comprising a portion of brake torque to be applied via regenerative braking and a portion of brake torque to be applied via friction braking. In a fifth example of the method, optionally including one or more or each of the first through fourth examples, the different simulation vehicle operating parameters comprise different simulated environmental road conditions, different simulated road routes, different simulated driver parameters, and/or different simulated calibratable vehicle parameters for each instance. In a sixth example of the method, optionally including one or more or each of the first through fifth examples, training the machine learning model comprises training the machine learning model to output, based on a set of vehicle input parameters, whether regenerative braking should be performed, a brake torque split that is to be applied during a braking event, and/or a regenerative braking torque threshold. In a seventh example of the method, optionally including one or more or each of the first through sixth examples, executing the simulation of each of the simulation set of vehicles the plurality of instances comprises executing the simulation of each of the simulation set of vehicles the plurality of instances in a distributed compute environment. In an eighth example of the method, optionally including one or more or each of the first through seventh examples, executing the simulation of each of the simulation set of vehicles the plurality of instances comprises executing each simulation in parallel. In a ninth example of the method, optionally including one or more or each of the first through eighth examples, each virtual vehicle of the simulation set of virtual vehicles is configured to simulate the one or more training vehicles, and wherein each training vehicle comprises a physical vehicle.

The disclosure also provides support for a system, comprising: one or more processors, and memory storing instructions executable by the one or more processors to: generate a simulation set of virtual vehicles based on a vehicle model, the vehicle model built based on sensor data collected from one or more training vehicles, execute a simulation of each of the simulation set of vehicles a plurality of instances, each instance executed with different simulation vehicle operating parameters, obtain simulation vehicle data from each of the simulation set of vehicles at each instance, train a machine learning model with the simulation vehicle data, and set one or more parameters of one or more real vehicles based on output from the trained machine learning model. In a first example of the system, the one or more processors and the memory are included in a distributed compute environment, and wherein each simulation is executed in parallel. In a second example of the system, optionally including the first example, each virtual vehicle of the simulation set of virtual vehicles is configured to simulate the one or more training vehicles, and wherein each training vehicle comprises a physical vehicle. In a third example of the system, optionally including one or both of the first and second examples, the different simulation vehicle operating parameters comprise different simulated environmental road conditions, different simulated road routes, different simulated driver parameters, and/or different simulated calibratable vehicle parameters for each instance. In a fourth example of the system, optionally including one or more or each of the first through third examples, setting the one or more parameters of the one or more real vehicles comprises sending an update to the one or more parameters to the one or more real vehicles using over-the-air capabilities.

The disclosure also provides support for a method executable on a distributed compute environment, comprising: generating a simulation set of virtual vehicles based on a vehicle model built from data collected from a real-world training vehicle, each virtual vehicle configured to simulate the real-world training vehicle, executing a simulation of each of the simulation set of vehicles a plurality of instances, each instance executed in parallel and with different simulation vehicle operating parameters, obtaining simulation vehicle data from each of the simulation set of vehicles at each instance, training a machine learning model with the simulation vehicle data, and setting one or more energy regeneration parameters of one or more real vehicles based on output from the trained machine learning model. In a first example of the method, the vehicle model is built from sensor data collected from a plurality of sensors on-board the real-world training vehicle and instrumentation data collected from a dynamometer on which the real-world training vehicle is operated. In a second example of the method, optionally including the first example, setting one or more energy regeneration parameters of the one or more real vehicles includes updating one or more calibratable energy regeneration parameters of each of the one or more real vehicles based on the output from the machine learning model. In a third example of the method, optionally including one or both of the first and second examples, the one or more calibratable energy regeneration parameters of each of the one or more real vehicles comprise one or more of conditions under which regenerative braking should be performed, a brake torque split that is to be applied during a braking event, and/or a regenerative braking torque threshold. In a fourth example of the method, optionally including one or more or each of the first through third examples, the different simulation vehicle operating parameters comprise different simulated environmental road conditions, different simulated road routes, different simulated driver parameters, and/or different simulated calibratable vehicle parameters for each instance.

While various embodiments have been described above, it should be understood that they have been presented by way of example, and not limitation. It will be apparent to persons skilled in the relevant arts that the disclosed subject matter may be embodied in other specific forms without departing from the spirit of the subject matter. The embodiments described above are therefore to be considered in all respects as illustrative, not restrictive.

Note that the example control and estimation routines included herein can be used with various powertrain and/or vehicle system configurations. The control methods and routines disclosed herein may be stored as executable instructions in non-transitory memory and may be carried out by the control system including the controller in combination with the various sensors, actuators, and other transmission and/or vehicle hardware. Further, portions of the methods may be physical actions taken in the real world to change a state of a device. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example examples described herein, but is provided for ease of illustration and description. One or more of the illustrated actions, operations and/or functions may be repeatedly performed depending on the particular strategy being used. Further, the described actions, operations and/or functions may graphically represent code to be programmed into non-transitory memory of the computer readable storage medium in the vehicle and/or transmission control system, where the described actions are carried out by executing the instructions in a system including the various hardware components in combination with the electronic controller. One or more of the method steps described herein may be omitted if desired.

It will be appreciated that the configurations and routines disclosed herein are exemplary in nature, and that these specific examples are not to be considered in a limiting sense, because numerous variations are possible. For example, the above technology can be applied to powertrains that include different types of propulsion sources including different types of electric machines, internal combustion engines, and/or transmissions. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

As used herein, the terms “approximately” and “substantially” are construed to mean plus or minus five percent of the range, unless otherwise specified.

1. A method, comprising:
building a vehicle model based on sensor data collected from one or more training vehicles;
generating a simulation set of virtual vehicles based on the vehicle model;
executing a simulation of each of the simulation set of vehicles a plurality of instances, each instance executed with different simulation vehicle operating parameters;
obtaining simulation vehicle data from each of the simulation set of vehicles at each instance;
training a machine learning model with the simulation vehicle data; and
setting one or more parameters of one or more real vehicles based on output from the trained machine learning model.

2. The method of claim 1, wherein building the vehicle model based on sensor data collected from one or more training vehicles comprises building the vehicle model based on sensor data from a first number of sensors each installed on the one or more training vehicles, and wherein the machine learning model is trained to take, as input, sensor data from a second number of sensors installed on the one or more real vehicles.

3. The method of claim 1, wherein updating the one or more real vehicles includes storing, in memory of the one or more real vehicles, the trained machine learning model.

4. The method of claim 1, wherein setting one or more parameters of the one or more real vehicles includes updating one or more calibratable vehicle parameters of each of the one or more real vehicles based on the output from the machine learning model.

5. The method of claim 4, wherein updating the one or more calibratable vehicle parameters comprises updating a braking dynamic equation configured to determine a brake torque split to apply during a braking event, the brake torque split comprising a portion of brake torque to be applied via regenerative braking and a portion of brake torque to be applied via friction braking.

6. The method of claim 1, wherein the different simulation vehicle operating parameters comprise different simulated environmental road conditions, different simulated road routes, different simulated driver parameters, and/or different simulated calibratable vehicle parameters for each instance.

7. The method of claim 1, wherein training the machine learning model comprises training the machine learning model to output, based on a set of vehicle input parameters, whether regenerative braking should be performed, a brake torque split that is to be applied during a braking event, and/or a regenerative braking torque threshold.

8. The method of claim 1, wherein executing the simulation of each of the simulation set of vehicles the plurality of instances comprises executing the simulation of each of the simulation set of vehicles the plurality of instances in a distributed compute environment.

9. The method of claim 1, wherein executing the simulation of each of the simulation set of vehicles the plurality of instances comprises executing each simulation in parallel.

10. The method of claim 1, wherein each virtual vehicle of the simulation set of virtual vehicles is configured to simulate the one or more training vehicles, and wherein each training vehicle comprises a physical vehicle.

11. A system, comprising:
one or more processors; and
memory storing instructions executable by the one or more processors to:
generate a simulation set of virtual vehicles based on a vehicle model, the vehicle model built based on sensor data collected from one or more training vehicles;
execute a simulation of each of the simulation set of vehicles a plurality of instances, each instance executed with different simulation vehicle operating parameters;
obtain simulation vehicle data from each of the simulation set of vehicles at each instance;
train a machine learning model with the simulation vehicle data; and
set one or more parameters of one or more real vehicles based on output from the trained machine learning model.

12. The system of claim 11, wherein the one or more processors and the memory are included in a distributed compute environment, and wherein each simulation is executed in parallel.

13. The system of claim 11, wherein each virtual vehicle of the simulation set of virtual vehicles is configured to simulate the one or more training vehicles, and wherein each training vehicle comprises a physical vehicle.

14. The system of claim 11, wherein the different simulation vehicle operating parameters comprise different simulated environmental road conditions, different simulated road routes, different simulated driver parameters, and/or different simulated calibratable vehicle parameters for each instance.

15. The system of claim 11, wherein setting the one or more parameters of the one or more real vehicles comprises sending an update to the one or more parameters to the one or more real vehicles using over-the-air capabilities.

16. A method executable on a distributed compute environment, comprising:
generating a simulation set of virtual vehicles based on a vehicle model built from data collected from a real-world training vehicle, each virtual vehicle configured to simulate the real-world training vehicle;
executing a simulation of each of the simulation set of vehicles a plurality of instances, each instance executed in parallel and with different simulation vehicle operating parameters;
obtaining simulation vehicle data from each of the simulation set of vehicles at each instance;
training a machine learning model with the simulation vehicle data; and
setting one or more energy regeneration parameters of one or more real vehicles based on output from the trained machine learning model.

17. The method of claim 16, wherein the vehicle model is built from sensor data collected from a plurality of sensors on-board the real-world training vehicle and instrumentation data collected from a dynamometer on which the real-world training vehicle is operated.

18. The method of claim 16, wherein setting one or more energy regeneration parameters of the one or more real vehicles includes updating one or more calibratable energy regeneration parameters of each of the one or more real vehicles based on the output from the machine learning model.

19. The method of claim 18, wherein the one or more calibratable energy regeneration parameters of each of the one or more real vehicles comprise one or more of conditions under which regenerative braking should be performed, a brake torque split that is to be applied during a braking event, and/or a regenerative braking torque threshold.

20. The method of claim 16, wherein the different simulation vehicle operating parameters comprise different simulated environmental road conditions, different simulated road routes, different simulated driver parameters, and/or different simulated calibratable vehicle parameters for each instance.
